(19) United States
(12) Patent Application Publication
(10) Pub. No.: US 2007/0006057 A1
(43) Pub. Date: Jan. 4, 2007

(54) Semiconductor memory chip and method of protecting a memory core thereof

(76) Inventors: Paul Wallner, Prien (DE); Andre Schaefer, Muenchen (DE); Thomas Hein, Muenchen (DE); Peter Gregorius, Muenchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/171,585

(22) Filed: Jun. 30, 2005

(51) Int. Cl. G11C 29/00

(52) U.S. Cl. 714/763

(57) ABSTRACT

Provided is a semiconductor memory chip that includes a memory core and an interface circuit having decoding, selecting and scheduling circuit means for decoding from a signal frame a respective type of data signals, command signals and address signals, selection of actions which are required in the memory chip according to the respective signal type and scheduling the memory core and sections of the interface circuit respectively for the decoded signal. The interface circuit further comprises a CRC bit decoding and check unit and a protection circuit arranged for protecting the memory core and for enabling/disabling switching through of signal transfer from the interface circuit to the memory core depending on a correct/incorrect signal generated by the CRC bit decoding and check unit according to the result of checking an information within the frame by means of the CRC bits which are inserted in a signal frame in association to the respective information in accordance with a defined transmission protocol.

### BACKGROUND

The present invention relates to a semiconductor memory chip and to a method of protecting a memory core thereof against incorrect information.

In future semiconductor memory systems data will be transmitted at very high frequencies. Transfer channel and system degenerates the transmitted signals and can lead to a loss of information. Loss of information means that a certain number of bits represented by BER (bit error rate for example 10⁻¹²) within the transmitted signal frame are wrong, for example since a certain bit has changed due to degeneration from logic “1” to “0”. Therefore, in future memory systems such errors are required to be detected and a system has to be protected from action enabled by such incorrect information. For this purpose additional CRC bits (Code Redundancy Check bits) are inserted at predetermined positions in the actual signal frame by which data, command and address signals are transmitted on the basis of a defined transmission protocol, or the CRC bits are transmitted on a separate link and aligned to the actual data stream to be checked. The more the number BER has to be reduced (for example to 10⁻²⁰) the more CRC bits are necessary and the more calculation has to be performed and the more latency increases.

Up to now data command address signals are transferred between a memory controller and memory chips of a memory system through separate data-command and address signal busses and not in form of signal frames on the basis of a defined transmission protocol. In prior art memory systems it has been assumed that BER is zero, because it is neglectable. However, with higher transmission frequencies this is no longer valid. In case that a bit error has occurred, wrong commands, data or addresses have been transmitted directly to the memory core. As a result non-deterministic errors can occur.

### SUMMARY

One embodiment of the present invention provides a semiconductor memory chip having means to protect the memory core from wrong commands, caused by bit errors due to transfer channel signal degeneration as well as a method of protecting a memory core of a semiconductor memory chip against incorrect information included in transmitted signal frames.

One embodiment of the present invention provides a semiconductor memory chip including a memory core and an interface circuit. The interface circuit is arranged for transferring synchronously with a clock signal data, command and address signals in form of signal frames on the basis of a defined transmission protocol from external of the memory chip to the memory core and from the memory core to the extern of the memory chip. The interface circuit includes decoding, selecting and scheduling circuit means respectively arranged for decoding from the signal frame a respective type of data signals, command signals and address signals, selection of actions which are required in the memory chip according to the respective signal type, and scheduling the memory core and sections of the interface circuit, respectively for the decoded signal. The interface circuit also includes a protection circuit arranged for protecting the memory core and for enabling/disabling signal transfer from the interface circuit to the memory core depending on information decoded and checked as being correct or incorrect on the basis of CRC-bits either included in the signal frame according to the transmission protocol or separately delivered through a separate CRC bit link and associated to the actual signal frame.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 schematically illustrates a functional block diagram of an interface circuit section of one embodiment of the present semiconductor memory chip.

FIG. 2 schematically illustrates a functional block diagram of an interface circuit section according to one embodiment of the present semiconductor memory chip.

FIG. 3 schematically illustrates a functional block diagram of an interface circuit section according to one embodiment of the present semiconductor memory chip.

FIG. 4 schematically illustrates a simplified example of a signal frame including code redundancy check bits at a certain position.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment of the present semiconductor memory chip includes the protection circuit such that it is possible to protect the memory core against a transfer of for example wrong command signals from the interface circuit on the basis of the CRC bits included in the signal frame.

In one embodiment of the present invention, the interface circuit of the semiconductor memory chip further includes a CRC-bit decoding and check unit arranged for decoding the CRC bits and associating it to information in the signal frame, checking said information as being correct or incorrect in dependence of said associated CRC bits and thereupon generating and outputting a correct/incorrect signal according to the result of checking said information, wherein said correct/incorrect signal is supplied to said protection circuit for enabling/disabling switching through of a signal transfer to the memory core.

According to one embodiment said CRC bit decoding and check unit includes a first circuit section arranged for decoding only special CRC bits and performing their association to predetermined special command signals being critical for system functions and/or memory functions for checking correctness/incorrectness the information of only these special command signals depending on the decoding operation, and a second circuit section arranged for decoding other CRC bits and performing their association to data, address and command signals not being critical for system functions and/or memory functions and for checking correctness/incorrectness of information of these non-critical data, address and command signals.

According to one embodiment a division of the CRC bit decoding and check unit in a first circuit section and a second circuit section is based on the fact that all commands in the signal frame which are critical to memory functions and/or system functions can be represented by a rather small number of frame bits. For this small number of frame bits it is much easier to perform a thorough CRC check in order to protect the DRAM core and a system to be accessed by bit error induced wrong commands. For all other data, address and command signals delivered in the signal frame CRC check can be carried out afterwards in the second circuit section because these other data, address and command bits cannot be harmful for the system function.

According to one embodiment of the present semiconductor memory chip said interface circuit is partitioned in a high frequency circuit part being synchronized with a high frequency clock signal and a low frequency circuit part being synchronized with a low frequency clock signal which is derived by frequency dividing said high frequency clock signal, wherein said decoding/selecting and scheduling circuit means and said protection circuit are arranged within said low frequency circuit part and synchronized with said low frequency clock signal, and said CRC bit decoding and check unit is arranged within said high frequency circuit part and synchronized with said high frequency clock signal.

In one embodiment of the present semiconductor memory chip said interface circuit is also partioned in a high frequency circuit part being synchronized with a high frequency clock signal and a low frequency circuit part being synchronized with a low frequency clock signal which is derived by frequency dividing said high frequency clock signal, wherein said decoding, selecting and scheduling circuit means, said protection circuit and said CRC bit decoding and check unit are arranged within said low frequency circuit part and synchronized by said low frequency clock signal.

In one embodiment, the present semiconductor memory chip is a DRAM memory core.

According to one embodiment, the present invention provides a method of protecting a memory core of a semiconductor memory chip against incorrect information included in a signal frame which is based on a defined transmission protocol and which is transferable from the extern of the memory chip through an interface circuit to the memory core. The method includes preliminarily generating and inserting CRC bits in predefined positions within the signal frame based on the transmission protocol or delivering separate CRC bits not embedded in the frame but aligned to the frame stream on a separate line to the memory chip so that data, command address signals included in the signal frame are at least partly checkable as to correct/incorrect information. The method also includes decoding said data, command and address signals in the signal frame, selecting actions required according to the type of said data, command and address signals and scheduling the decoded signals to said memory core and said interface circuit respectively. The method also includes decoding the CRC bits and comparing the same to CRC information derived and generated from the data, command and address signals and checking correctness/incorrectness of the data, command and address signals by means of the comparison. The method also includes enabling/disabling transfer of the decoded signals to said memory core depending on the correctness/incorrectness result of the CRC signal check.

With a smart protocol definition all commands in the signal frame which are critical for the system function or the memory function can be represented by a rather small number of frame bits. Therefore a small number of CRC check bits is sufficient to protect the memory core and the system against erroneous information. In one case, the present method includes separate decoding of special CRC bits as associated to predetermined command signals which are critical for system functions and/or memory functions, checking correctness/incorrectness of these critical command signals on the basis of these special CRC bits and enabling/disabling transfer of only these critical command signals to the memory core, depending on the check result.

In one embodiment, the present semiconductor memory chip is a DRAM memory core and the enabling/disabling of signal transfer is carried out using the special command signals: “activate”, “self-refresh” and “precharge.” “Activate” commands activation of a memory bank, “self-refresh” commands to carry out a charge refresh and “precharge” commands to carry out closing of a memory bank of a DRAM-semiconductor memory.

As has been mentioned before, data, command and address signals are transferred within the present semiconductor memory chip as well as between these semiconductor memory chips and a memory controller in a memory system synchronously with a clock signal in the form of signal frames on the basis of a defined transmission protocol.

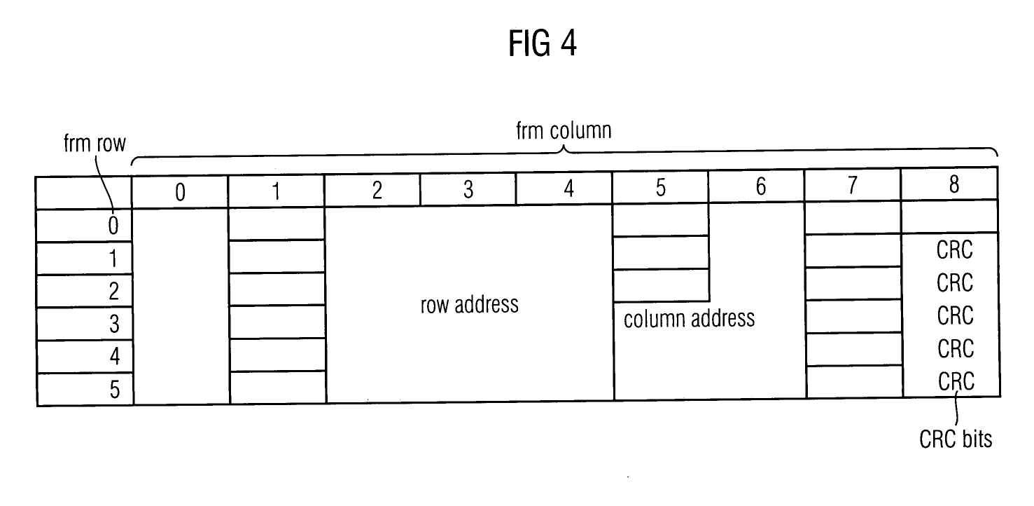

FIG. 4 schematically illustrates an exemplified construction for example of a command signal frame having eight command signal columns and one CRC column in six rows, wherein this frame is constructed according to a defined transmission protocol, which provides the additional CRC bits accompanying the actual frame.

Although the example of the command signal frame illustrated in FIG. 4 includes the CRC bits each in form of single bits for each row 1-5, each CRC information may comprise more than one bit if not only a simple error detection is desired. The more the bit error rate BER has to be reduced, for example from 10⁻¹² to 10⁻¹², the more CRC bits are necessary.

According to the illustration in FIG. 4, the CRC bits are defined at certain locations in the frame. The latter is in accordance with the protocol specification. Moreover, also the algorithm, how such CRC bits can be calculated is a part of the protocol specification. However, as already mentioned, CRC bits may be transferred through a separate link from the memory controller to the memory chip and there associated to the signals of the actual frame.

Until now, if a bit error has occurred, wrong commands, data or addresses have been transmitted directly to the memory core. As a result non-deterministic errors could occur.

Therefore, one embodiment of the present invention provides a structure of the interface circuit of a semiconductor memory chip that can check incoming frames for bit errors before decoded commands are switched through to the memory core.

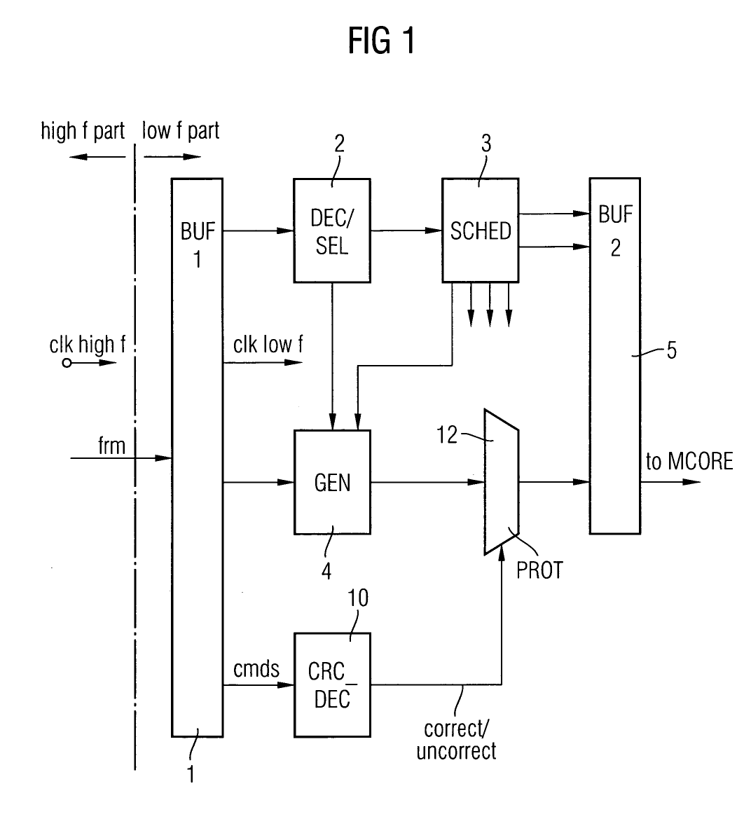

The following description describes structural and functional features of embodiments of the present interface circuit with reference to FIGS. 1 to 3, wherein like circuit blocks and functional blocks are referenced by the same reference signs.

The functional block diagram schematically depicted in FIG. 1 illustrates on its right-hand side a low frequency part of an interface circuit according to one embodiment of the invention arranged in a semiconductor memory chip for transferring data, command and address signals in form of signal frames frn synchronously with a clock signal on the basis of a defined transmission protocol. In FIG. 1, the dotted line symbolizes demultiplexing circuits bringing the clock frequency down and parallelizing the frames frm. The frame frm from a high frequency interface circuit part (partly illustrated in the left-hand side) is demultiplexed, parallelized and fed to the low frequency part of the interface circuit which includes a first buffer circuit (BUF) 1, a decoding and selection circuit part (DEC/SEL) 2 for decoding a respective type of data signals, command signals and address signals from the signal frame and selecting actions which are required in the memory chip according to the respective signal type, a scheduler (SCHED) 3 for scheduling the memory core (MCORE) and sections of the interface circuit respectively for the decoded signals, a command generator (GEN) 4, which includes units for generating memory and system commands (not shown), a protection circuit (PROT) 12 arranged for protecting MCORE and enabling/disabling transfer of a signal to MCORE depending on information checked as being correct or incorrect on the basis of the CRC bits included in the signal frame (refer to the above and to FIG. 4).

One embodiment includes in the low frequency interface circuit section illustrated in FIG. 1 a CRC bit decoder (CRC-DEC) 10 for checking incoming signal frames at first for bit errors and their association to the information in the signal frame. CRC-DEC 10 checks the information as being correct or incorrect using the associated CRC bit(s) and thereupon generates and outputs a correct/incorrect signal according to the result of checking said information. The correct/incorrect signal generated by CRC-DEC is supplied to PROT 12 for enabling/disabling transfer of the information signals to MCORE. That is according to one embodiment of the present invention, the result of the check bit evaluation carried out by CRC-DEC 10 serves as switch enabling/disabling decoded commands from GEN 4 to pass/pass not through PROT 12 the second buffer circuit BUF 2 and from there to MCORE.

While in the interface circuit according to the embodiment illustrated in FIG. 1 CRC-DEC 10 decodes all CRC bits included in the signal frame FRM and thereupon checks the associated information as being correct or incorrect, it is evident that PROT 12 according to correct/incorrect signal of CRC-DEC 10 enables or disables switching through of all commands generated by GEN 4.

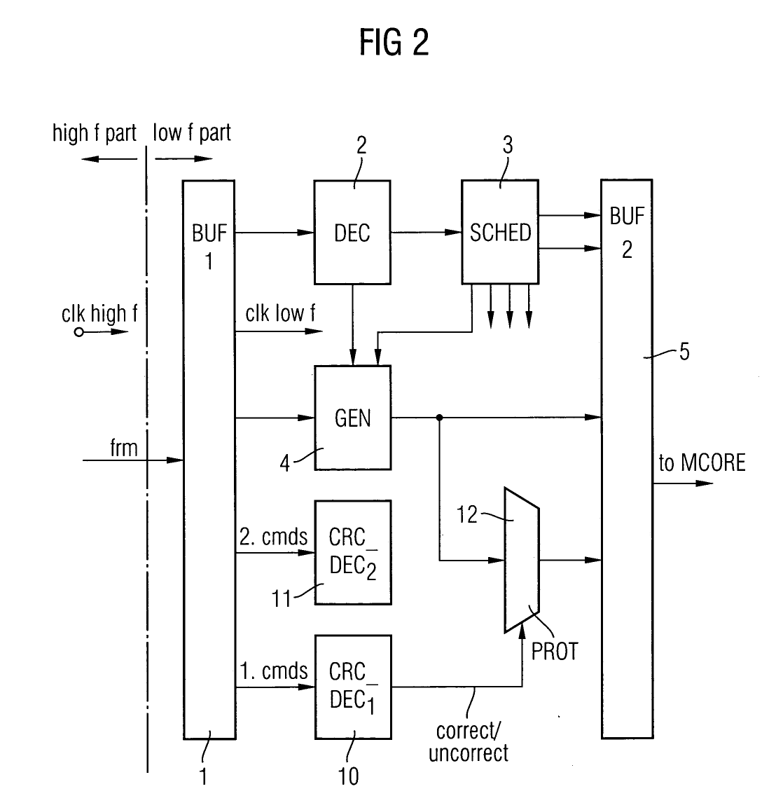

The interface circuit according to the embodiment schematically depicted in FIG. 2 includes a first CRC-bit decoding and check unit (CRC-DEC 1) 10 and a second CRC-bit decoding and check unit (CRC-DEC 2) 11. Namely, considering the relevant DRAM/system commands which can harm the system significantly, only a few commands remain, for example an “activate” command which is a command for opening a memory bank of the semiconductor memory, a “self-refresh” command which is a command for refreshing the charge in case the semiconductor memory is a DRAM memory and a “precharge” command which is a command for closing a memory bank. With a smart protocol definition all critical parts of the frame where sensible information is stored such as the commands mentioned above can be represented by a rather small number of frame bits. For this small number of frame bits it is much easier to perform a thorough CRC check in order to protect the memory and the system to be accessed by bit error induced wrong commands. Therefore the first CRC bit decoding and check unit 10 receives from BUF 1 only those parts of the frame, for example, critical commands that can harm the system significantly and the CRC bits associated thereto while the second CRC bit decoding and check unit 11 receives all other commands and the CRC bits associated thereto.

Upon checking said relevant memory/system commands that can harm the system significantly by means of the associated CRC bits, only CRC-DEC 1 10 will generate the correct/incorrect signal which, is supplied to PROT 12. For all other data bits delivered within the frame the second CRC-DEC 2 11 will check correctness/incorrectness of the related information afterwards because harmful system access is not possible for them.

The embodiment illustrated in FIG. 2 represents a frame decoder within an interface circuit having a CRC bit decoding and check unit divided in first CRC-DEC 1 10 arranged for decoding only special CRC bits in the signal frame and their association to predetermine special command signals being critical for system and memory function and for checking in accordance with this decoding correctness/incorrectness of the information of only these special command signals and second CRC-DEC 2 11 arranged for decoding the other CRC bits in the signal frame and their association to data/address and command signals not being critical for system and memory function. CRC-DEC 1 10 as well as CRC-DEC 2 11 are both located in the low frequency domain of the interface circuit as it is the case with CRC-DEC 10 in the interface circuit according to the embodiment illustrated in FIG. 1.

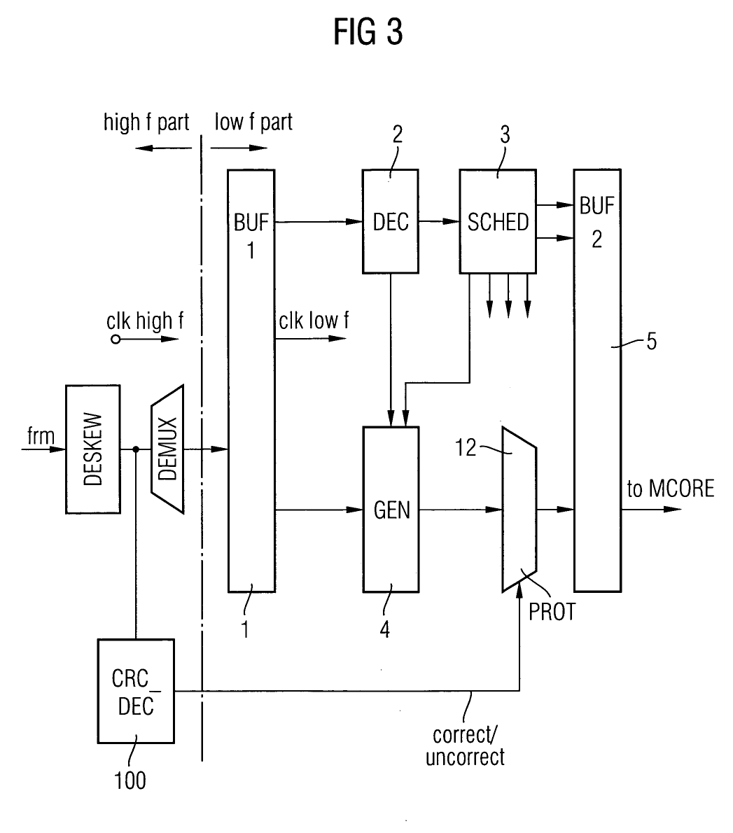

Different from the embodiments of the present semiconductor memory chip illustrated in FIGS. 1 and 2, the embodiment illustrated in FIG. 3, provides a CRC bit decoding and check unit CRC-DEC 100 in the high frequency part of the interface circuit. In the high frequency part illustrated in the left part of FIG. 3 a circuit unit DESKEW carries out a de-skewing (lane-wise alignment) of a signal frame frm. Thereupon frm is transferred to a demultiplexer DEMUX and from there to the low frequency part of the interface circuit which is depicted in the right hand part of FIG. 3. At the same time frm de-skewed by DESKEW is sent to CRC-DEC 100 and CRC checked. As a result the correct/incorrect signal is available from CRC/DEC 100 and used for enabling/disabling PROT 12 to switch through or inhibit the transfer of the information, that is the command generated by the command generator 4, to MCORE or other system parts.

With the embodiment illustrated in FIG. 3, more CRC bits can be calculated including more frame bits at once due to the higher frequency in the high frequency part. Calculation of a single parity bit increases BER, however, can be typically performed with a number of shift registers or XOR gates depending on the number of included data bits to be checked. More CRC bits reduce BER, but need larger circuits for calculation. Therfore to calculate more than one CRC bit is more latency expensive because in this case more shift registers have to be established.

With the embodiment illustrated in FIG. 3, bit error rate BER can be reduced due to increased information about wrong bits.

With the embodiment illustrated in FIG. 3, the latency impact is small, because CRC checking is performed at high frequencies.

Bearing in mind the above, one skilled in the art will easily recognize that one embodiment of a semiconductor memory chip of the present invention may include a DRAM memory core. However, the embodiments of the present invention discussed above are not restricted to DRAM memories but relate to a method of protecting a memory core of a semiconductor memory chip against incorrect information included in a signal frame that is based on a defined transmission protocol and that is transferable from the extern of the memory chip through an interface circuit to the memory core. One embodiment of the method includes the following steps:
preliminarily generating and inserting CRC bits in predefined positions within the signal frame based on the transmission protocol or delivering separate CRC bits not embedded in the frame but aligned to the frame stream on a separate line to the memory chip so that data, command address signals included in the signal frame are at least partly checkable as to correct/incorrect information;
decoding said data, command and address signals in the signal frame, selecting actions required according to the type of said data, command and address signals and scheduling the decoded signals to said memory core and said interface circuit respectively;
decoding the CRC bits and comparing: the same to CRC information derived and generated from the data, command and address signals as decoded and checking correctness/incorrectness of the data, command and address signals by means of the comparison and
enabling/disabling transfer of signals decoded to said memory core depending on the correctness/incorrectness result of the CRC signal check.

Obviously many modifications and variations of the present invention are possible in light of the above description. It is therefore to be understood, that within the scope of appended claims the invention may be practiced otherwise than as specifically deviced.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor memory chip comprising:
a memory core; and
an interface circuit arranged for transferring synchronously with a clock signal data, command and address signals in form of signal frames on the basis of a defined transmission protocol from external of the memory chip to the memory core and from the memory core to the extern of the memory chip, wherein said interface circuit comprises:
decoding, selecting and scheduling circuit means respectively arranged for decoding from the signal frame a respective type of data signals, command signals and address signals, for selection of actions which are required in the memory chip according to the respective signal type, and for scheduling the memory core and sections of the interface circuit, respectively for the decoded signal; and
a protection circuit arranged for protecting the memory core and for enabling/disabling signal transfer from the interface circuit to the memory core depending on information decoded and checked as being correct or incorrect on the basis of CRC-bits either included in the signal frame according to the transmission protocol or separately delivered through a separate CRC bit link and associated to the actual signal frame.

2. The semiconductor memory chip of claim 1, wherein said interface circuit further comprises a CRC bit decoding and check unit arranged for decoding the CRC bits and associating it to information in the signal frame, checking said information as being correct or incorrect in dependence of said associated CRC bits and thereupon generating and outputting a correct/incorrect signal according to the result of checking said information, wherein said correct/incorrect signal is supplied to said protection circuit for enabling/disabling the switching through of a signal transfer to the memory core.

3. The semiconductor memory chip of claim 2, wherein said CRC bit decoding and check unit comprises:
a first circuit section arranged for decoding only special CRC bits and performing their association to predetermined special command signals being critical for system functions and/or memory functions and for checking correctness/incorrectness of the information of only these special command signals depending on the decoding operation; and
a second circuit section arranged for decoding other CRC bits and performing their association to data, address and command signals not being critical for system functions and/or memory functions and for checking correctness/incorrectness of information of these non-critical data, address and command signals.

4. The semiconductor memory chip of claim 1, wherein said interface circuit is partitioned in a high frequency circuit part being synchronized with a high frequency clock signal and a low frequency circuit part being synchronized with a low frequency clock signal which is derived by frequency dividing said high frequency clock signal, wherein said decoding/selecting and scheduling circuit means and said protection circuit are arranged within said low frequency circuit part and synchronized with said low frequency clock signal, and said CRC bit decoding and check unit is arranged within said high frequency circuit part and synchronized with said high frequency clock signal.

5. The semiconductor memory chip of claim 1, wherein said interface circuit is partitioned in a high frequency circuit part being synchronized with a high frequency clock signal and a low frequency circuit part being synchronized with a low frequency clock signal which is derived by frequency dividing said high frequency clock signal, wherein said decoding, selecting and scheduling circuit means, said protection circuit and said CRC bit decoding and check unit are arranged within said low frequency circuit part and synchronized by said low frequency clock signal.

6. The semiconductor memory chip of claim 1, wherein it comprises a DRAM memory core.

7. A method of protecting a memory core of a semiconductor memory chip against incorrect information included in a signal frame that is based on a defined transmission protocol and that is transferable from the extern of the memory chip through an interface circuit to the memory core, said method comprising:
preliminarily generating and inserting CRC bits in predefined positions within the signal frame based on the transmission protocol so that data, command address signals included in the signal frame are at least partly checkable as to correct/incorrect information;
decoding of said data, command and address signals in the signal frame, selecting of actions required according to the type of said data, command and address signals and scheduling the decoded signals to said memory core and said interface circuit respectively;
decoding the CRC bits in the signal frame, associating the same to the data, command and address signals and checking correctness/incorrectness of the data, command and address signals by means of said associated CRC signals; and
enabling/disabling transfer of the decoded signals to said memory core depending on the correctness/incorrectness result of the CRC signal check.

8. The method of claim 7, wherein decoding the CRC bits includes a separate decoding of special CRC bits as associated to predetermined command signals being critical for system functions and memory functions and checking correctness/incorrectness of these critical command signals on the basis of the special CRC bits and enabling/disabling transfer of only these critical command signals to the memory core depending on the check result.

9. The method of claim 8, wherein enabling/disabling the transfer is carried out for the special command signals “activate”, “self-refresh” and “precharge”, wherein “activate” commands activation of a memory bank, “self-refresh” commands to carry out a charge refresh and “precharge” commands to carry out closing of a memory bank of a DRAM-semiconductor memory.

10. A semiconductor memory chip comprising:
a memory core;
decoding means for decoding from a signal frame a respective type of data signals, command signals and address signals;
selecting means for selecting actions that are required in the semiconductor memory chip according to the respective signal type;
scheduling means for scheduling the memory core the decoded signal;
wherein the decoding means, selecting means and scheduling means collectively form an interface arranged to transfer synchronously with a clock signal data, command and address signals in the form of signal frames on the basis of a defined transmission protocol to and from the memory core and external to the memory chip; and
protection means for protecting the memory core and for enabling/disabling signal transfer from the interface to the memory core depending on information decoded and checked as being correct or incorrect on the basis of CRC-bits.

11. The semiconductor memory chip of claim 10, wherein the CRC-bits are included in the signal frame according to the transmission protocol.

12. The semiconductor memory chip of claim 10, wherein the CRC-bits are separately delivered through a separate CRC bit link and associated to the actual signal frame.

13. The semiconductor memory chip of claim 10, further comprising CRC bit decoding means for decoding the CRC bits and associating it to information in the signal frame.

14. The semiconductor memory chip of claim 13, further comprising checking means for checking the information in the signal frame as being correct or incorrect in dependence of the associated CRC bits.

15. The semiconductor memory chip of claim 14, wherein a correct/incorrect signal is generated and output according to the result of checking the information in the signal frame, and wherein the correct/incorrect signal is supplied to the protection means for enabling/disabling the switching of a signal transfer to the memory core.

16. The semiconductor memory chip of claim 15, wherein checking and CRC bit decoding means further comprise a first circuit section arranged for decoding only special CRC bit and performing their association to predetermined special command signals being critical for systems and memory functions and for checking correctness/incorrectness of the information of only these special command signals depending on the decoding operation.

17. The semiconductor memory chip of claim 16, wherein checking and CRC bit decoding means further comprise a second circuit section arranged for decoding other CRC bits and performing their association to data, address and command signals not being critical for system functions and/or memory functions and for checking correctness/incorrectness of information of these non-critical data, address and command signals.

18. The semiconductor memory chip of claim 10, wherein said interface circuit is partitioned in a high frequency circuit part being synchronized with a high frequency clock signal and a low frequency circuit part being synchronized with a low frequency clock signal which is derived by frequency dividing said high frequency clock signal, wherein said decoding/selecting and scheduling circuit means and said protection circuit are arranged within said low frequency circuit part and synchronized with said low frequency clock signal, and said CRC bit decoding and check unit is arranged within said high frequency circuit part and synchronized with said high frequency clock signal.

19. The semiconductor memory chip of claim 10, wherein said interface circuit is partitioned in a high frequency circuit part being synchronized with a high frequency clock signal and a low frequency circuit part being synchronized with a low frequency clock signal which is derived by frequency dividing said high frequency clock signal, wherein said decoding, selecting and scheduling circuit means, said protection circuit and said CRC bit decoding and check unit are arranged within said low frequency circuit part and synchronized by said low frequency clock signal.

20. The semiconductor memory chip of claim 10, wherein it comprises a DRAM memory core.
